(19) United States
(12) Patent Application Publication
(10) Pub. No.: US 2013/0188993 A1
(43) Pub. Date: Jul. 25, 2013

(54) SURFACE-EMITTING SEMICONDUCTOR LASER, SURFACE-EMITTING SEMICONDUCTOR LASER DEVICE, OPTICAL TRANSMISSION DEVICE, AND INFORMATION PROCESSING DEVICE

(71) Applicants: Takashi KONDO, Kanagawa (JP); Kazutaka TAKEDA, Kanagawa (JP); Hideo NAKAYAMA, Kanagawa (JP)

(72) Inventors: Takashi KONDO, Kanagawa (JP); Kazutaka TAKEDA, Kanagawa (JP); Hideo NAKAYAMA, Kanagawa (JP)

(73) Assignee: FUJI XEROX CO., LTD., Tokyo (JP)

(21) Appl. No.: 13/552,190

(22) Filed: Jul. 18, 2012

(30) Foreign Application Priority Data
Jan. 20, 2012 (JP) 2012-010273

(51) Int. Cl. H01S 5/00; G02B 27/18; G03G 15/04

(52) U.S. Cl. 399/221; 372/45.01; 362/259

(57) ABSTRACT

A surface-emitting semiconductor laser includes a substrate, a first n-type semiconductor multi-layer reflecting mirror formed on the substrate including a pair of a high refractive index layer with a relatively high refractive index and a low refractive index layer with a low refractive index which are laminated, an n-type semiconductor layer formed on the first semiconductor multi-layer reflecting mirror, having an optical film thickness greater than an oscillation wavelength, and including Al and Ga, an active region formed on the semiconductor layer, and a second p-type semiconductor multi-layer reflecting mirror formed on the active region and including a pair of a high refractive index layer with a relatively high refractive index and a low refractive index layer with a low refractive index which are laminated, wherein an n-type impurity dopant injected into the semiconductor layer is a group VI material or Sn.

### CROSS-REFERENCE TO RELATED APPLICATIONS

This application is based on and claims priority under 35 USC 119 from Japanese Patent Application No. 2012-010273 filed Jan. 20, 2012.

### BACKGROUND

### Technical Field

The present invention relates to a surface-emitting semiconductor laser, a surface-emitting semiconductor laser device, an optical transmission device, and an information processing device.

### SUMMARY

According to an aspect of the invention, there is provided a surface-emitting semiconductor laser including a substrate, a first n-type semiconductor multi-layer reflecting mirror that is formed on the substrate and includes a pair of a high refractive index layer with a relatively high refractive index and a low refractive index layer with a low refractive index which are laminated, an n-type semiconductor layer that is formed on the first semiconductor multi-layer reflecting mirror, has an optical film thickness greater than an oscillation wavelength, and includes Al and Ga, an active region that is formed on the semiconductor layer, and a second p-type semiconductor multi-layer reflecting mirror that is formed on the active region and includes a pair of a high refractive index layer with a relatively high refractive index and a low refractive index layer with a low refractive index which are laminated, wherein an n-type impurity dopant injected into the semiconductor layer is a group VI material or Sn.

### BRIEF DESCRIPTION OF THE DRAWINGS

Exemplary embodiments of the present invention will be described in detail based on the following figures, wherein:

FIGS. 1A and 1B are schematic cross-sectional views illustrating a vertical-cavity surface-emitting semiconductor laser according to a first example of the invention;

FIG. 2A is a diagram illustrating the energy band of AlGaAs;

FIG. 2B is a diagram illustrating an energy band for describing the DX center of n-type AlGaAs;

FIG. 3 is a graph illustrating the relationship between the energy level of the DX center and a Γ level when Si is used as an impurity dopant of AlGaAs;

FIG. 4 is a diagram illustrating the energy band of an Al_{0.32}Ga_{0.68}As conductor when Si is used as a dopant and an Al composition is about 32%;

FIG. 5A is a diagram illustrating the energy band of an AlGaAs conductor when Si is used as the dopant and the Al composition is less than about 22%;

FIG. 5B is a diagram illustrating the energy band of the AlGaAs conductor when. Si is used as the dopant and the Al composition is equal to or more than about 22%;

FIGS. 6A to 6D are diagrams schematically illustrating aspects in which the coupling between atoms by the DX center is broken when a group IV material and a group VI material are used as the impurity dopant of AlGaAs;

FIG. 7A is a graph illustrating the DLTS (Deep Level Transient Spectroscopy) measurement result of the group IV material;

FIG. 7B is a graph illustrating the DLTS measurement result of the group VI material;

FIG. 8 is a table illustrating the DLTS measurement results of a group IV impurity material (donor) and a group VI impurity material (donor);

FIG. 9 is a graph illustrating the relationship between the energy band and the Al composition of an Al_{X}Ga_{1-X}As conductor when Te, which is a group VI material, is used;

FIGS. 10A and 10B are schematic cross-sectional views illustrating the structure of a surface-emitting semiconductor laser device in which an optical member is mounted on the surface-emitting semiconductor laser according to this example;

FIG. 11 is a diagram illustrating an example of the structure of a light source device using the surface-emitting semiconductor laser according to this example; and

FIG. 12 is a schematic cross-sectional view illustrating the structure of an optical transmission device using the surface-emitting semiconductor laser device shown in FIG. 10A.

### DETAILED DESCRIPTION

Hereinafter, exemplary embodiments of the invention will be described with reference to the accompanying drawings. A surface-emitting semiconductor laser (VCSEL: Vertical Cavity Surface Emitting Laser) is used in a light source of a communication device or an image forming apparatus. In the surface-emitting semiconductor laser used in the light source, it is necessary to improve the optical output or ESD (Electro Static Discharge) resistance in a single transverse mode and reduce the resistance value or the amount of heat generated, thereby increasing the lifespan of an element.

In a selectively oxidized surface-emitting semiconductor laser, the diameter of an oxide aperture of a current blocking layer is reduced to about 3 microns, thereby obtaining the single transverse mode. However, when the diameter of the oxide aperture is reduced, the resistance of the element increases and the heating temperature also increases, which causes a reduction in the lifespan. When the diameter of the oxide aperture is reduced, the optical output is also reduced. Increasing the length of a cavity is considered as a method of increasing the optical output and lifespan of the surface-emitting semiconductor laser. Typically, the vertical-cavity surface-emitting semiconductor laser includes a cavity with a cavity length of about 3 microns to 4 microns (about ten to twenty times the oscillation wavelength). When the length of the cavity increases, the difference between optical loss in the basic transverse mode in which the spread angle is small and optical loss in the high-order transverse mode in which the spread angle is large increases. As a result, even when the diameter of the oxide aperture increases, it is possible to obtain the single transverse mode. In the vertical-cavity surface-emitting semiconductor laser, it is possible to increase the diameter of the oxide aperture to about 8 microns and increase the optical output to about 5 mW.

In the following description, a selectively oxidized long-cavity surface-emitting semiconductor laser is given as an example and the surface-emitting semiconductor laser is referred to as a VCSEL. It is noted that the scale of the drawings is emphasized for easy understanding of the characteristics of the invention, and is not necessarily equal to the actual scale of devices.

### EXAMPLES

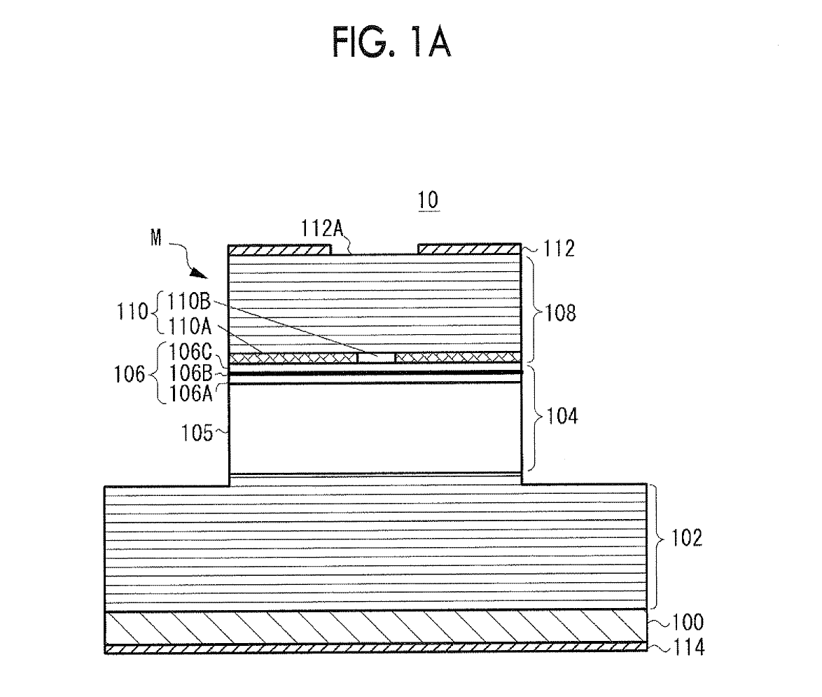

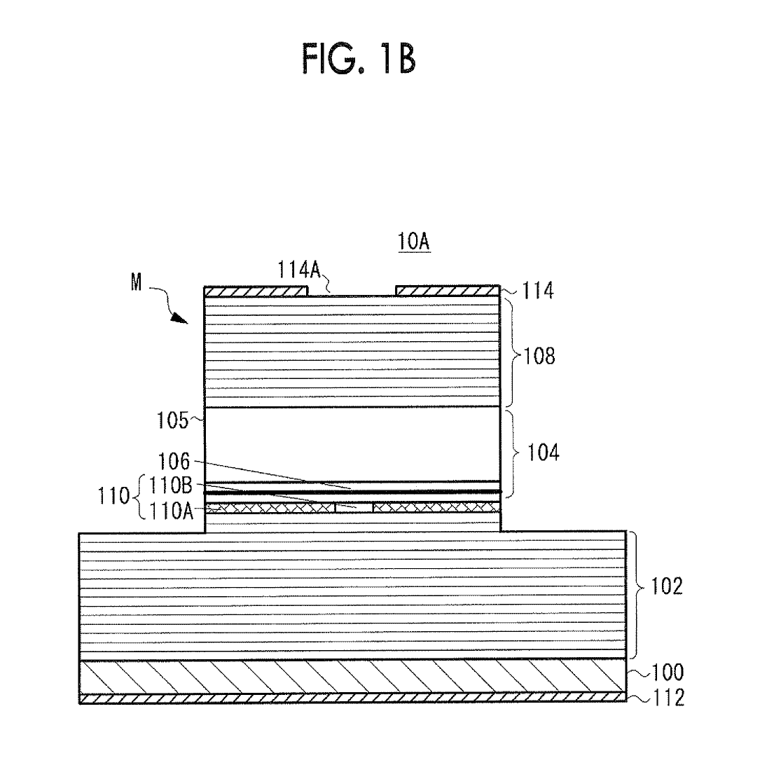

FIG. 1A is a schematic cross-sectional view illustrating a long-cavity VCSEL according to a first example of the invention. As shown in FIG. 1A, a long-cavity VCSEL 10 according to this example is formed by laminating a lower n-type distributed Bragg reflector (hereinafter, referred to as a DBR) 102 that is obtained by alternately overlapping AlGaAs layers with different Al compositions, a cavity 104 that is formed on the lower DBR 102 and provides a vertical cavity structure, and an upper p-type DBR 108 that is formed on the cavity 104 and is obtained by alternately overlapping AlGaAs layers with different Al compositions on an n-type GaAs substrate 100.

The lower n-type DBR 102 is formed by alternately laminating, for example, 40 pairs of Al_{0.9}Ga_{0.1}As layers and Al_{0.3}Ga_{0.7}As layers each of which has a thickness of λ/4nᵣ (where X is an oscillation wavelength and nᵣ is the refractive index of a medium). After silicon, which is an n-type impurity, is doped, carrier concentration is, for example, about 3×10¹⁸ cm⁻³. In addition, the p-type upper DBR 108 is formed by alternately laminating 29 pairs of p-type Al_{0.9}Ga_{0.1}As layers and Al_{0.3}Ga_{0.7}As layers each of which has a thickness of λ/4nᵣ. After carbon, which is a p-type impurity, is doped, carrier concentration is, for example, about 3×10¹⁸ cm⁻³. Preferably, a contact layer made of p-type GaAs is formed on the uppermost layer of the upper DBR 108 and a current blocking layer 110 made of p-type AlAs or AlGaAs is formed on the lowermost layer of the upper DBR 108 or inside the upper DBR 108.

The cavity 104 includes a cavity extended region 105, which is an n-type semiconductor layer formed on the lower DBR 102, and an active region 106 which is formed on the cavity extended region 105. The active region 106 includes upper and lower spacer layers 106A and 106C and a quantum well active layer 1063 interposed therebetween. It is preferable that the thickness of the active region 106 be equal to the oscillation wavelength λ. The lower spacer layer 106A is, for example, an undoped Al_{0.6}Ga_{0.4}As layer. The quantum well active layer 106B is an undoped Al_{0.11}Ga_{0.89}As quantum well layer and an undoped Al_{0.3}Ga_{0.7}As barrier layer. The upper spacer layer 106C is an undoped Al_{0.6}Ga_{0.4}As layer.

The cavity extended region 105 is a monolithic layer which is formed by a series of epitaxial growth processes and has an arbitrary optical film thickness. For example, the optical film thickness of the cavity extended region 105 may be several times to tens of times greater than λ (λ is the oscillation wavelength). A VCSEL without a long cavity does not include the cavity extended region 105. In general, in the VCSEL without a long cavity, the active region 106 is formed on the lower DBR 102 and the optical film thickness of the cavity 104 is equal to or less than λ. The cavity extended region 105 may also be referred to as a resonator extended region or a cavity space.

In this example, the cavity extended region 105 is a semiconductor layer including Al and Ga and is preferably made of AlGaAs. In the cavity extended region 105, a group VI material or Sn is used as an n-type impurity dopant in order to prevent the generation of a DX center and the influence thereof. Examples of the group VI material include Se, Te, and S.

The semiconductor layers from the upper DBR 108 to the lower DER 102 are etched to form a cylindrical mesa (columnar structure) M on the substrate 100. The current blocking layer 110 is exposed from the side surface of the mesa M and includes an oxidized region 110A which is selectively oxidized from the side surface and a conductive region (oxide aperture) 110E which is surrounded by the oxidized region 110A. The planar shape of the surface of the conductive region 110E which is parallel to the main surface of the substrate 100 is a circle to which the outward shape of the mesa M is reflected and the center of the surface of the conductive region 110B is substantially aligned with the optical axis of the mesa M in the axial direction. In the long-cavity VCSEL 10, in order to obtain the basic transverse mode, the diameter of the conductive region 110B may be more than that in the general VCSEL. For example, the diameter of the conductive region 110B may be increased to about 7 to 8 microns.

An annular p-side electrode 112 which is a laminate of, for example, Ti and Au and is made of a metal material is formed on the uppermost layer of the mesa M. The p-side electrode 112 comes into ohmic contact with the contact layer of the upper DBR 108. A circular opening, that is, a light emission hole 112A through which light is emitted is formed in the p-side electrode 112. The center of the light emission hole 112A is aligned with the optical axis of the mesa M. In addition, an n-side electrode 114 is formed on the rear surface of the substrate 100.

When the VCSEL without the long cavity is operated in the single transverse mode, it has one resonance wavelength, that is, one longitudinal mode since the length of the cavity is short. On the other hand, in the long-cavity VCSEL according to this example, since the cavity length is long, plural resonance wavelengths may be generated. The number of resonance wavelengths generated is proportional to the cavity length. Therefore, in the VCSEL with the long cavity structure, the switching of the resonance wavelength (the switching of the longitudinal mode) is likely to occur due to, for example, a variation in operation current and a kink is likely to be generated in IL characteristics indicating the relationship between an input current and a laser output. Since the switching of the resonance wavelength is not preferable for the high-speed modulation of the VCSEL, it is preferable to reduce the difference between the refractive indexes of the pair of AlGaAs layers forming the lower DBR 102 or the difference between the refractive indexes of the pair of AlGaAs layers forming the upper DBR 108, narrow the reflection band of reflectance (for example, 99% or more) capable of performing laser oscillation, select a desired resonance wavelength from the plural resonance wavelengths, and prevent the switching of the longitudinal mode.

In the long-cavity VCSEL, it is preferable that the n-type cavity extended region 105 be used. The reason is that the n-type cavity extended region 105 absorbs a small amount of light and the resistance of an element may be reduced. When the material forming the cavity extended region 105 is AlGaAs and Si is used as the impurity dopant, doping concentration is affected and there are a very large number of DX centers with a deep level, which causes rapid deterioration of the active layer 106B. The DX center has a deep level generated in a conductor and is presumed to be an As defect which occurs due to the injection of impurities, which are a donor, into AlGaAs or GaAs.

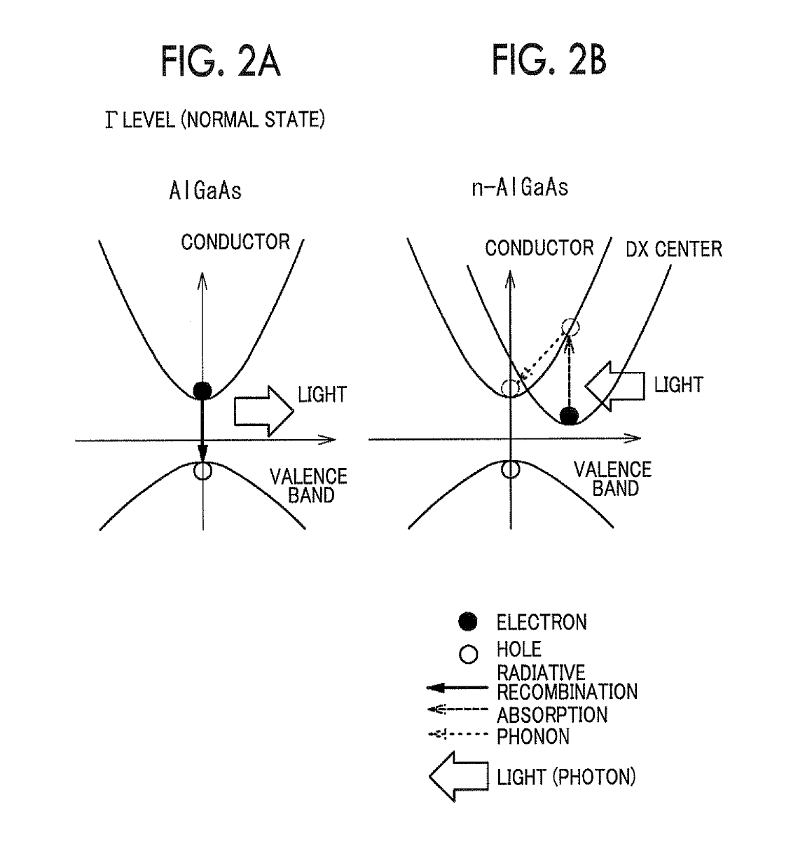

FIG. 2A shows the energy band of n-type AlGaAs in a normal state (Γ level) and FIG. 2E shows an energy band when the DX center is generated in the n-type AlGaAs. As shown in FIG. 2A, an electron in the conductor is coupled to a hole in the valence band to generate light (photons). In AlGaAs in which an Al composition is equal to or more than about 20%, the deep level of the DX center lower than the Γ level shown in FIG. 2A is formed and the electron is likely to be trapped at the DX center. At that time, for a group IV donor, the donor is moved and, for a group VI donor, Ga (Al) is moved. The electron is accumulated in the DX center, absorbs light, is released from the DX center, and returns to the conductor. At that time, for the group IV donor, the donor is moved and, for the group VI donor, Ga (Al) is moved. This is one of the causes of destruction of the crystal structure of the active layer and significant deterioration of the characteristics.

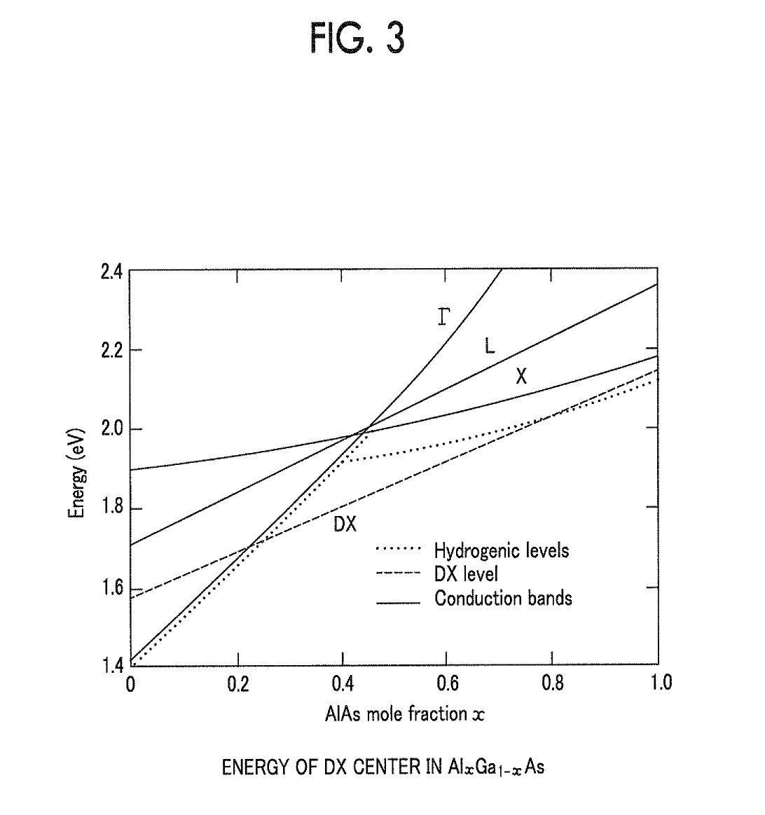

FIG. 3 is a graph illustrating the relationship between the energy band and the Al composition of an Al_{X}Ga_{1-X}As conductor (Applied Physics Letters, Volume 65, Issue 2, 1996, “Dx Center and Bistability of Compound Semiconductor”, Mineo Saito). As shown in FIG. 2A, Γ indicates a general energy level without crystal defects and the DX center indicates an energy level when Si is used as the impurity dopant. Here, when the Al composition (X) is equal to or more than approximately 22%, the level of the DX center is lower than the Γ level. That is, when Si is used as the impurity dopant and the Al composition of Al_{X}Ga₁₋ₓAs is equal to or more than approximately 22%, the deep level of the DX center is lower than the Γ level in the normal state and electrons are likely to be trapped at the DX center.

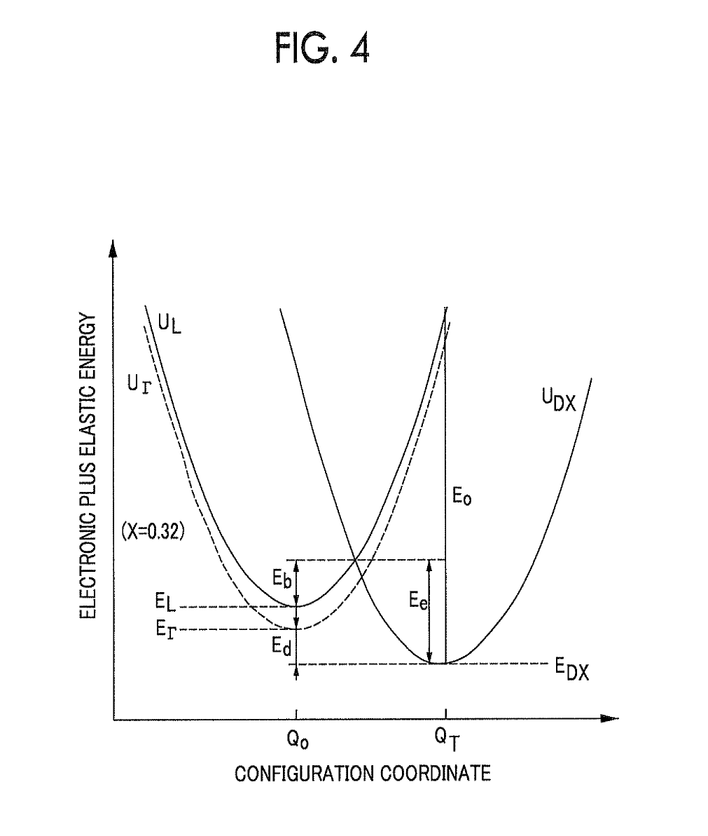

FIG. 4 shows the energy band structure of an Al_{0.32}Ga_{0.68}As conductor when Si is used as a dopant and the Al composition is about 32% (Applied Physics Letters, Volume 65, Issue 2, 1996, “Dx Center and Bistability of Compound Semiconductor”, Mineo Saito). The DX center is fixed to an L band, Eb, Ee, and Eo depend on the dopant, and the Γ band and the L band are changed when the Al composition is changed, (where Eb is capture energy, Ed is donor binging energy, Ee is activation energy, and Bo is optical ionization energy).

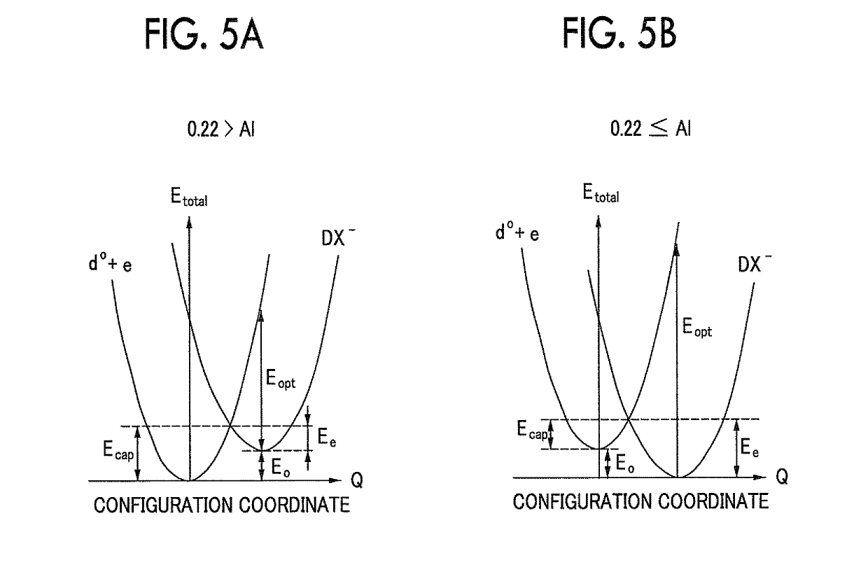

FIG. 5A shows the band structure of an AlGaAs conductor when Si is used as the dopant and the Al composition is less than about 22%, and FIG. 5B shows the band structure of the AlGaAs conductor when Si is used as the dopant and the Al composition is equal to or more than about 22%. As can be seen from FIGS. 5A and 5B, the deep level of the DX center is higher than the Γ level in the normal state when the Al composition is less than about 22%, and is lower than the Γ level and is stabilized when the Al composition is equal to or more than about 22%.

In the first example of the invention, a group VI material is used as the impurity dopant of the cavity extended region 105 to form AlGaAs. When Te, Se, or S, which is a group VI material, is used as the impurity dopant, the deep level of the DX center is higher than the deep level when Si, which is a group IV material, is used. Therefore, the deep level may be lower than that when Si is used, the rate of occurrence of the DX center in the cavity extended region 105 is reduced, and the number of electrons trapped at the DX center is reduced, which makes it possible to prevent crystal defects or crystal destruction of the active layer due to the DX center.

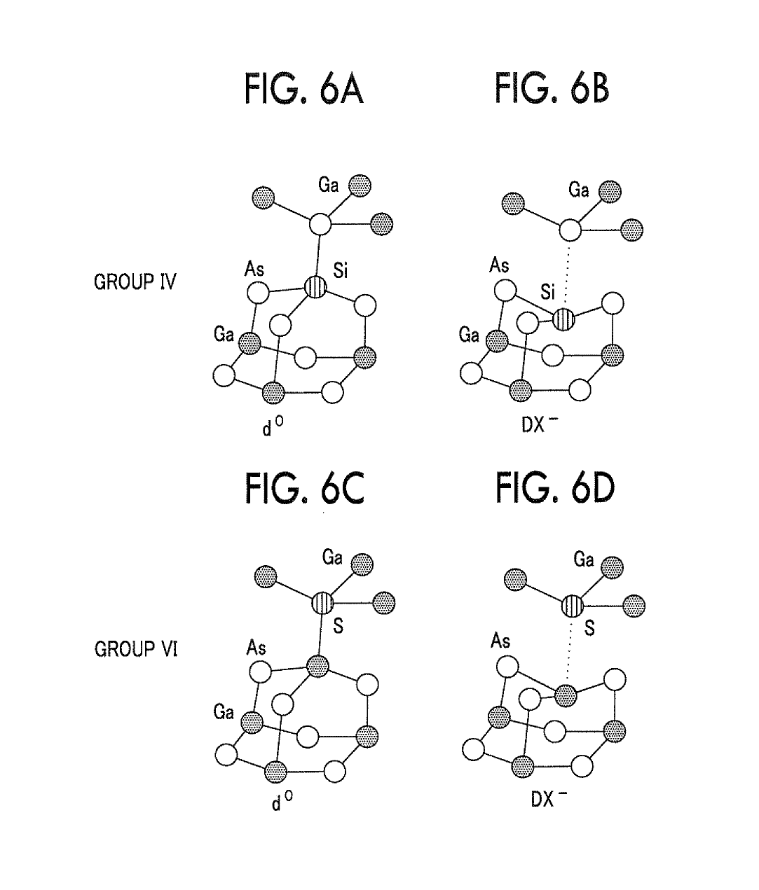

FIGS. 6A to 6D are diagrams schematically illustrating aspects in which atoms are decoupled due to the DX center when a group IV material and a group VI material are used as the impurity dopant of AlGaAs. FIGS. 6A to 6D are disclosed in Phys. Rev. B Vol. 39, Num. 14, 1989 pp. 10063, “Energetics of DX-center formation In GaAs and AlxGa1−xAs alloys”, D. J. Chadi et al.

It is considered that the DX center is caused by the lack of As and an n-type dopant. FIG. 6A shows a normal state when Si is injected as the group IV material. When two electrons are trapped at the DX center, the coupling of Ga—Si is broken and the state is changed to that shown in FIG. 6B. In this case, an Si atom is moved. When light with energy equal to or more than Eo is absorbed, electrons are released and the state returns to that shown in FIG. 6A.

FIG. 6C shows a normal state when S is injected as the group VI material. When two electrons are trapped at the DX center, the coupling of Ga—S is broken and the state is changed to that shown in FIG. 6D. In this case, a Ga atom is moved. When light with energy equal to or more than Eo is absorbed, electrons are released and the state returns to that shown in FIG. 6C. As such, the atom moved by the DX center varies depending on whether the group IV impurities or the group VI impurities are used.

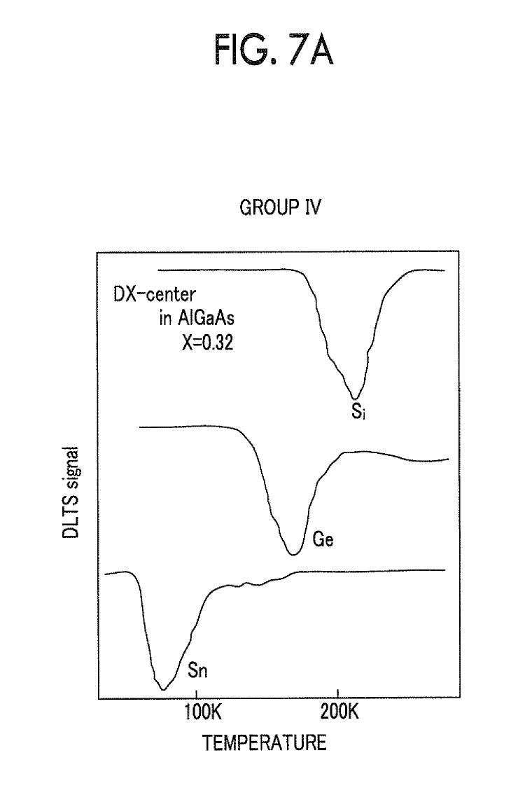

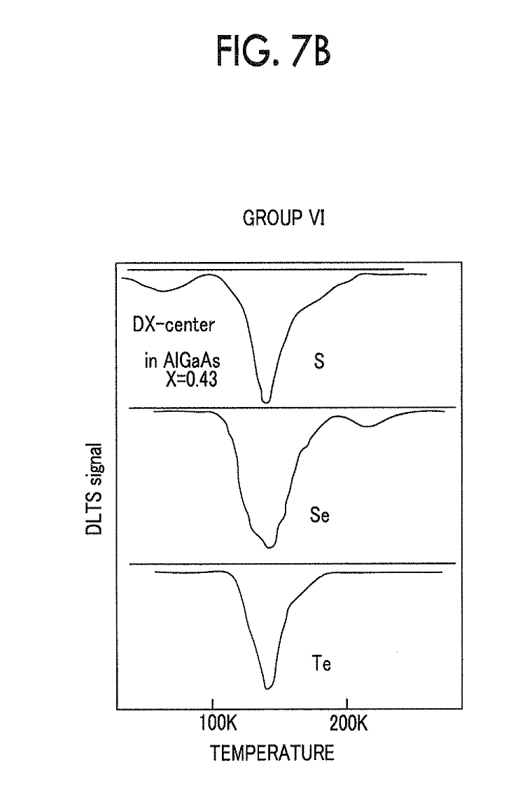

FIG. 7A is a graph illustrating the measurement result of the deep level using DLTS (Deep Level Transient Spectroscopy) when a group IV impurity material is used in Al_{0.32}a_{0.68}As and FIG. 7B is a graph illustrating the measurement result of the deep level using DLTS when a group VI impurity material is used in Al_{0.43}a_{0.57}As. In FIGS. 7A and 7B, the horizontal axis is the temperature and the vertical axis is the energy of a DLTS waveform. These graphs are disclosed in Appl. Phys. Lett 45 (12) 15 Dec. 1322-1323, “Chemical trends in the activation energies of DX centers”, O. Kumagai et al. As shown in FIG. 7A, the temperature at which the peak of the DLTS waveform by the group IV impurities appears varies depending on the dopant material, and the peak positions of Ge and Sn, which are impurities with a large mass number than that of Si, tend to shift toward a low temperature as the mass number increases. In addition, in the group IV material, as the temperature increases, the energy of the DX center becomes deeper. In the group VI material, such as S, Se, or Te, the temperature at which the peak of the DLTS waveform appears does not vary depending on the dopant material, but is substantially constant. The reason is that, in the group VI material, only Ga is moved. As can be seen from FIGS. 7A and 73, the level of the DX center by Si is the deepest.

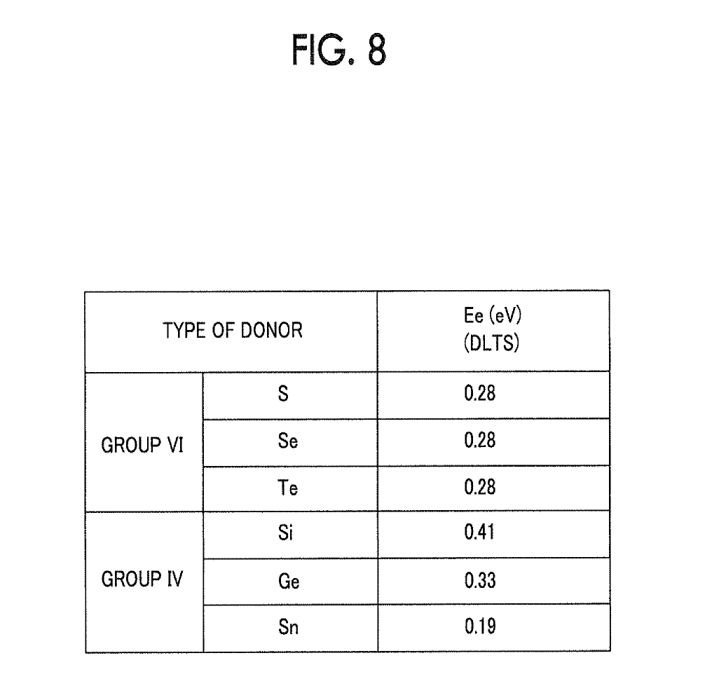

FIG. 8 is a table illustrating the value (DLTS value) of the DX center for a group IV donor and a group VI impurity material. This table is quoted from “Properties of Aluminum Gallium Arsenide”, Sadao Adachi, pp. 279. In the table, an energy value represented by Ee indicates the deep level of the DX center. Since Si, which is a group IV material, has the largest DLTS value of 0.41, the level of the DX center from the F level is the deepest. In contrast, S, Se, and Te, which are group VI materials, have the same DLTS value of 0.28. This is because Ga is moved in the group VI material. However, in the group IV material, since the DLTS value of Sn is 0.19 and is less than that in the group VI material, the level of the DX center from the Γ level is shallow.

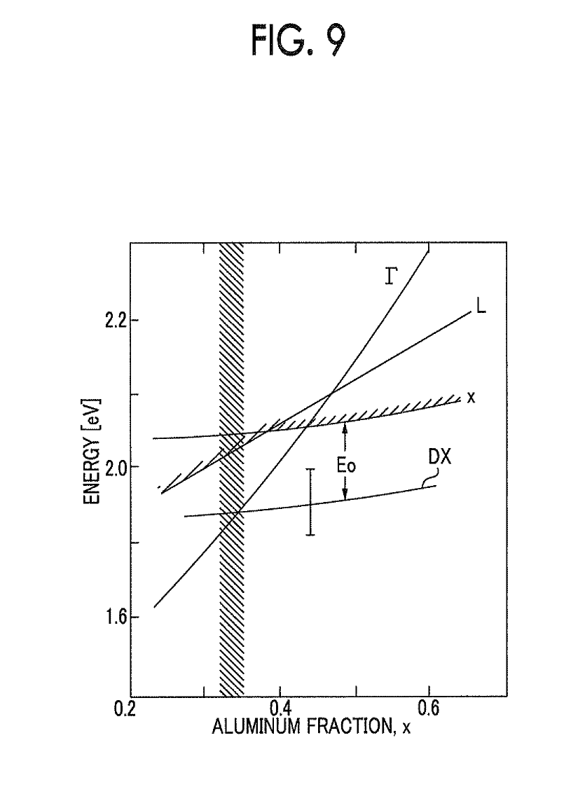

FIG. 9 is a graph illustrating the relationship between the energy band and the Al composition of an Al_{X}Ga_{1-X}As conductor when Te, which is a group VI material, is used. This graph is quoted from Phys. Rev. B Vol. 19 Num. 2 1979, pp. 1015, “Trapping Characteristics and a donor-complex (DX) model for the persistent-Photo conductivity trapping center in Te-doped AlxGa1−xAs”, D. V. Lang et al. As can be seen from FIG. 9, the deep level of the DX center intersects the Γ level in the Al composition range of about 32% to 35%. When the Al composition is equal to or more than about 35%, the deep level of the DX center is lower than the Γ level.

The long-cavity VCSEL according to this example has an oscillation wavelength of about 700 nm to 850 nm. When the oscillation wavelength is less than about 700 nm, the Al composition of the cavity extended region 105 made of AlGaAs needs to be about 30% to 40% or more. Even when a group-IV or group-VI n-type dopant is used, the deep level of the DX center is lower than the Γ level. Therefore, the Al composition is affected by the DX center. On the other hand, when the oscillation wavelength is greater than about 850 nm, the Al composition of the cavity extended region 105 made of AlGaAs is equal to or less than about 18%. In this case, even when a group-IV or group-VI n-type dopant is used, the deep level of the DX center is higher than the F level. Therefore, the DX center is not generated.

In the first example, when the oscillation wavelength of the VCSEL is in the range of about 700 nm to 850 nm, the Al composition is in the range of about 18% to 40%. In order to minimize influence by the DX center, a group VI material is used as the impurity dopant of the cavity extended region 105. The deep level of the DX center when a group VI material, such as Te, Se, or S, is used is lower than the deep level of the DX center when Si is used, as described with reference to FIGS. 7A and 7B and FIG. 8. Therefore, even when a group VI dopant is used, the deep level of the DX center is lower than the Γ level in the normal state without crystal defects, but the deep level is not as deep as that when Si is used. Therefore, as compared to when Si is used, the rate of occurrence of the DX center is reduced and it is possible to reduce the number of electrons trapped. In this way, a reduction in the lifespan due to the deterioration of the crystal structure of the active layer 106B caused by the DX center is prevented and it is possible to improve the reliability of the long-cavity VCSEL.

Next, a second example of the invention will be described. In the first example, the group IV material is used as the dopant of the cavity extended region 105 made of AlGaAs. However, in the second example, Sn, which is a group IV material, is used as a dopant material. As shown in FIGS. 7A and 7B and FIG. 8, Sn is a group IV material in which the deep level (about 0.19 eV) of the DX center is lower than that in Si or Ge, which is another group IV material, and that in 5, Se, or Te, which is a group VI material. Therefore, even when Sn is used as an n-type dopant, the level which is as deep as that when Si is used is not formed. As a result, it is possible to reduce the rate of occurrence of the DX center or the number of electrons trapped by the DX center.

The exemplary embodiments of the invention have been described above, but the invention is not limited to a specific exemplary embodiment. Various modifications and changes of the invention may be made without departing from the scope and spirit of the invention described in the claims. For example, in the above-described example, the lower DER 102 and the upper DBR 108 include a pair of a high AlGaAs layer with a high Al composition ratio and a low AlGaAs layer with a low Al composition ratio. However, the lower DBR 102 and the upper DBR 108 is not limited to AlGaAs. The lower DBR 102 and the upper DER 108 may include a pair of a high refractive index layer with a relatively high refractive index and a low refractive index layer with a low refractive index. For example, GaAs serving as the high refractive index layer and AlGaAs serving as the low refractive index layer may be combined with each other. When the oscillation wavelength is long, GaAs may be used in the DBR.

In the first example, the n-type GaAs substrate is used to form the long-cavity VCSEL 10. However, a p-type GaAs substrate may be used. In this case, as shown in FIG. 1B, the p-type lower DBR 102 is formed on the p-type GaAs substrate 100, the cavity 104 is formed on the p-type lower DBR 102, and the n-type upper DBR 108 is formed on the cavity 104. Thep-type current blocking layer 110 is formed at a position close to the active region 106 of the lower DBR 102. The cavity 104 includes the active region 106 and an n-type cavity extended region (spacer layer). The n-side electrode 114 is formed on the upper DBR 108. A light emission hole 114A is formed at the center of the n-side electrode 114 and the p-side electrode 112 is formed on the rear surface of the substrate 100.

In the above-described example, the optical film thickness of the cavity extended region 105 is about 16λ, but is an illustrative example. Preferably, the optical film thickness of the cavity extended region 105 is selected from the range of about 10λ to 20λ. However, it is noted that, when the cavity length increases, the number of resonance wavelengths increases in proportion to the cavity length. The difference between the refractive indexes (in this example, the difference between the Al compositions) of the high refractive index layer and the low refractive index layer forming the lower DBR or the upper DBR is appropriately selected from the relationship with the possible resonance wavelength. That is, the refractive index difference is selected such that a reflection band in which the reflectance of the resonance wavelength which is not desired is reduced may be obtained.

The diameter of the conductive region (oxide aperture) 110B of the current blocking layer 110 may be appropriately changed depending on, for example, a required optical output. In the above-described exemplary examples, laser light is emitted from the top of the mesa (columnar structure) M formed on the substrate. However, the mesa is not indispensable. When the mesa M is not formed, laser light may be emitted from the rear surface of the substrate. In this case, since the reflectance of the lower DBR 102 is less than that of the upper DBR 108, the number of pairs of the low refractive index layers and the high refractive index layers in the upper DBR 108 is greater than that in the lower DBR and an emission window is formed in the n-side electrode 114. The n-side electrode 114 is not necessarily formed on the rear surface of the substrate 100, but may be directly electrically connected to the lower DBR 102. In this case, the substrate 100 may be made of a semi-insulating material.

A buffer layer may be formed between the GaAs substrate 100 and the lower DER 102, if necessary. In the above-described examples, the GaAs-based VCSEL is given as an example. However, the examples of the invention may be applied to other long-cavity VCSELs using group III-V compound semiconductors. In the above-described example, the single-spot VCSEL is given as an example. However, the examples of the invention may be applied to a multi-spot VCSEL or a VCSEL array in which a large number of mesas (light emitting units) are formed on a substrate.

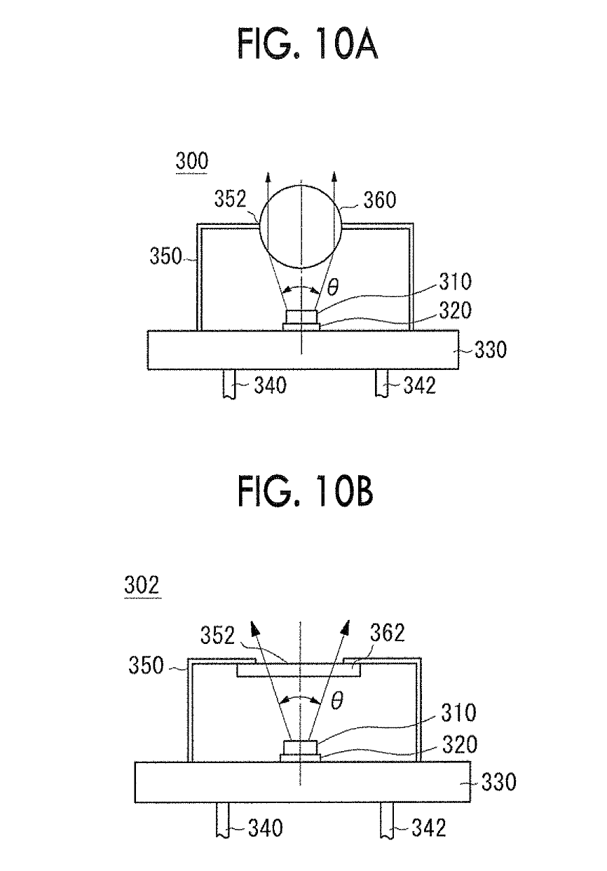

Next, a surface-emitting semiconductor laser device, an optical information processing device, and an optical transmission device using the VCSEL according to this example will be described with reference to the drawings. FIG. 10A is a cross-sectional view illustrating the structure of the surface-emitting semiconductor laser device including the VCSEL and an optical member mounted (packaged) thereon. In a surface-emitting semiconductor laser device 300, a chip 310 on which a long-cavity VCSEL is formed is fixed to the upper surface of a disk-shaped metal stem 330 through a conductive adhesive 320. Conductive leads 340 and 342 are inserted into through hole (not shown) formed in the stem 330. One lead 340 is electrically connected to the n-side electrode of the VCSEL and the other lead 342 is electrically connected to the p-side electrode.

A rectangular hollow cap 350 is fixed to the upper surface of the stem 330 including the chip 310 and a ball lens 360, which is an optical member, is fixed in an opening 352 which is formed at the center of the cap 350. The ball lens 360 is positioned such that the optical axis thereof is aligned substantially with the center of the chip 310. When a forward voltage is applied between the leads 340 and 342, laser light is emitted from the chip 310 in the vertical direction. The distance between the chip 310 and the ball lens 360 is adjusted such that the ball lens 360 is included in the spread angle θ of laser light from the chip 310. A light receiving element for monitoring the light emission state of the VCSEL or a temperature sensor may be included in the cap.

FIG. 10B is a diagram illustrating the structure of another surface-emitting semiconductor laser device. In a surface-emitting semiconductor laser device 302 shown in FIG. 10B, instead of the ball lens 360, a flat glass 362 is fixed in the opening 352 formed at the center of the cap 350. The flat glass 362 is positioned such that the center thereof is aligned substantially with the center of the chip 310. The distance between the chip 310 and the flat glass 362 is adjusted such that the aperture diameter of the flat glass 362 is equal to or greater than the spread angle θ of laser light from the chip 310.

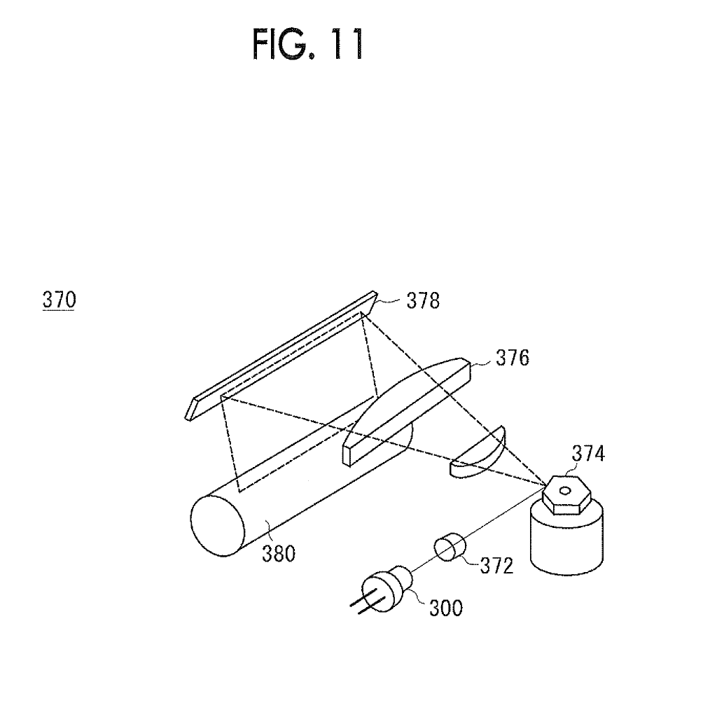

FIG. 11 is a diagram illustrating an example of the application of the VCSEL to a light source of the optical information processing device. An optical information processing device 370 includes a collimator lens 372 on which laser light from the surface-emitting semiconductor laser device 300 or 302 provided with the long-cavity VCSEL shown in FIG. 10A or FIG. 10B is incident, a polygon mirror 374 that is rotated at a constant speed and reflects a light beam from the collimator lens 372 at a constant spread angle, an fθ lens 376 on which the laser light from the polygon mirror 374 is incident and emits light to a reflecting mirror 378, the reflecting mirror 378 with a linear shape, and a photoconductor drum (recording medium) 380 that forms a latent image on the basis of the reflected light from the reflecting mirror 378. As such, the VCSEL may be used as a light source of an optical information processing device, such as a copying machine or a printer including an optical system that focuses laser light emitted from the VCSEL on a photoconductor drum and a mechanism that scans the photoconductor drum with the focused laser light.

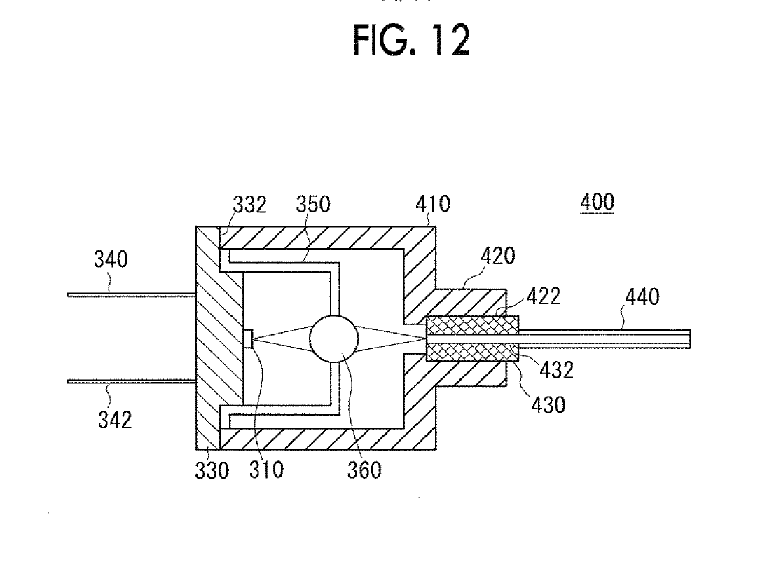

FIG. 12 is a cross-sectional view illustrating the structure of an optical transmission device to which the surface-emitting semiconductor laser device shown in FIG. 10A is applied. An optical transmission device 400 includes a cylindrical housing 410 that is fixed to the stem 330, a sleeve 420 that is formed integrally with the end surface of the housing 410, a ferrule 430 that is held in an opening 422 of the sleeve 420, and an optical fiber 440 that is held by the ferrule 430. The end of the housing 410 is fixed to a flange 332 that is formed in the circumferential direction of the stem 330. The ferrule 430 is accurately positioned in the opening 422 of the sleeve 420 and the optical axis of the optical fiber 440 is matched with the optical axis of the ball lens 360. The core of the optical fiber 440 is held in a through hole 432 of the ferrule 430.

Laser light emitted from the surface of the chip 310 is focused by the ball lens 360 and the focused light is incident on the core of the optical fiber 440 and is then transmitted. In the above-mentioned example, the ball lens 360 is used. However, other lenses, such as a biconvex lens and a plano-convex lens, may be used. In addition, the optical transmission device 400 may include a driving circuit for applying electric signals to the leads 340 and 342. The optical transmission device 400 may have a reception function for receiving optical signals through the optical fiber 440.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various exemplary embodiments and with the various modifications as are suited to the particular use contemplated. It is intended that the scope of the invention be defined by the following claims and their equivalents.

What is claimed is:

1. A surface-emitting semiconductor laser comprising:
a substrate;
a first n-type semiconductor multi-layer reflecting mirror that is formed on the substrate and includes a pair of a high refractive index layer with a relatively high refractive index and a low refractive index layer with a low refractive index which are laminated;
an n-type semiconductor layer that is formed on the first semiconductor multi-layer reflecting mirror, has an optical film thickness greater than an oscillation wavelength, and includes Al and Ga;
an active region that is formed on the semiconductor layer; and
a second p-type semiconductor multi-layer reflecting mirror that is formed on the active region and includes a pair of a high refractive index layer with a relatively high refractive index and a low refractive index layer with a low refractive index which are laminated,
wherein an n-type impurity dopant injected into the semiconductor layer is a group VI material or Sn.

2. A surface-emitting semiconductor laser comprising:
a substrate;
a first p-type semiconductor multi-layer reflecting mirror that is formed on the substrate and includes a pair of a high refractive index layer with a relatively high refractive index and a low refractive index layer with a low refractive index which are laminated;
an active region that is formed on the first semiconductor multi-layer reflecting mirror;
an n-type semiconductor layer that is formed on the active region, has an optical film thickness greater than an oscillation wavelength, and includes Al and Ga; and
a second n-type semiconductor multi-layer reflecting mirror that is formed on the semiconductor layer and includes a pair of a high refractive index layer with a relatively high refractive index and a low refractive index layer with a low refractive index which are laminated,
wherein an n-type impurity dopant injected into the semiconductor layer is a group VI material or Sn.

3. The surface-emitting semiconductor laser according to claim 1,
wherein the length of a cavity defined by the first semiconductor multi-layer reflecting mirror, the semiconductor layer, the active region, and the second semiconductor multi-layer reflecting mirror is greater than the oscillation wavelength,
at least two resonance wavelengths are included in a reflection band of the cavity, and
oscillation occurs with a selected resonance wavelength.

4. The surface-emitting semiconductor laser according to claim 2,
wherein the length of a cavity defined by the first semiconductor multi-layer reflecting mirror, the semiconductor layer, the active region, and the second semiconductor multi-layer reflecting mirror is greater than the oscillation wavelength,
at least two resonance wavelengths are included in a reflection band of the cavity, and
oscillation occurs with a selected resonance wavelength.

5. The surface-emitting semiconductor laser according to claim 1,
wherein the Al composition of the semiconductor layer is equal to or more than about 22%.

6. The surface-emitting semiconductor laser according to claim 2,
wherein the Al composition of the semiconductor layer is equal to or more than about 22%.

7. The surface-emitting semiconductor laser according to claim 3,
wherein the Al composition of the semiconductor layer is equal to or more than about 22%.

8. The surface-emitting semiconductor laser according to claim 1,
wherein the Al composition of the semiconductor layer is equal to or less than about 35%.

9. The surface-emitting semiconductor laser according to claim 2,
wherein the Al composition of the semiconductor layer is equal to or less than about 35%.

10. The surface-emitting semiconductor laser according to claim 3,
wherein the Al composition of the semiconductor layer is equal to or less than about 35%.

11. The surface-emitting semiconductor laser according to claim 1,
wherein the group VI material is Se, Te, or S.

12. The surface-emitting semiconductor laser according to claim 1,
wherein the oscillation wavelength is in a range of about 700 nm to 850 nm.

13. The surface-emitting semiconductor laser according to claim 1,
wherein the semiconductor layer is an Al_{X}Ga_{1-X}As layer and 0.22≦X≦0.35 is satisfied.

14. The surface-emitting semiconductor laser according to claim 1,
wherein each of the high refractive index layers and the low refractive index layers of the first and second semiconductor multi-layer reflecting mirrors is a semiconductor layer including Al.

15. The surface-emitting semiconductor laser according to claim 1,
wherein the semiconductor layer is a single layer that is epitaxially grown on the first semiconductor multi-layer reflecting mirror.

16. The surface-emitting semiconductor laser according to claim 1, further comprising:
a p-type current blocking layer that is provided close to the active region.

17. The surface-emitting semiconductor laser according to claim 16,
wherein a columnar structure is formed on the substrate, and
the current blocking layer includes an oxidized region which is selectively oxidized from a side surface of the columnar structure and a conductive region which is surrounded by the oxidized region.

18. A surface-emitting semiconductor laser device comprising:
the surface-emitting semiconductor laser according to claim 1; and
an optical member on which light from the surface-emitting semiconductor laser is incident.

19. An optical transmission device comprising:
the surface-emitting semiconductor laser device according to claim 18; and
a transmission unit that transmits laser light emitted from the surface-emitting semiconductor laser device through an optical medium.

20. An information processing device comprising:
the surface-emitting semiconductor laser according to claim 1;
a focusing unit that focuses laser light emitted from the surface-emitting semiconductor laser on a recording medium; and
a mechanism that scans the recording medium with the laser light focused by the focusing unit.
